(19) United States
(12) Patent Application Publication
(10) Pub. No.: US 2010/0059738 A1
(43) Pub. Date: Mar. 11, 2010

(54) Conductive Polymer Compositions in Opto-Electrical Devices

(75) Inventors: Jeremy Burroughes, Cambridge (GB); Keng Hoong Yim, Cambridge (GB); Ji-Seon Kim, Cambridge (GB)

Correspondence Address: MARSHALL, GERSTEIN & BORUN LLP, 233 SOUTH WACKER DRIVE, 6300 SEARS TOWER, CHICAGO, IL, 60606-6357, US

(73) Assignees: CAMBRIDGE DISPLAY TECHNOLOGY LIMITED, Cambridgeshire (GB); CAMBRIDGE UNIVERSITY TECHNICAL SERVICES LIMITED, Cambridge (GB)

(21) Appl. No.: 12/440,212

(22) PCT Filed: Sep. 7, 2007
(86) PCT No.: PCT/GB07/03383

§ 371 Date: Nov. 13, 2009

(30) Foreign Application Priority Data
Sep. 8, 2006 (GB) 0617723.2

(51) Int. Cl. H01L 51/10; H01L 51/40; H01B 1/12

(52) U.S. Cl. 257/40; 438/29; 525/540; 525/535; 257/E51.019; 257/E21.158

(57) ABSTRACT

A conductive polymer composition comprising: a polymer having a HOMO level greater than or equal to −5.7 eV and a dopant having a LUMO level less than −4.3 eV.

### FIELD OF INVENTION

This invention relates to conductive polymer compositions and opto-electrical devices comprising conductive polymer compositions.

### BACKGROUND OF INVENTION

One class of opto-electrical devices is that using an organic material for light emission or detection. The basic structure of these devices is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO 90/13148 the organic light-emissive material is a polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide “ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium.

In operation, holes are injected into the device through the anode and electrons are injected into the device through the cathode. The holes and electrons combine in the organic electroluminescent layer to form an exciton which then undergoes radiative decay to give light.

These devices have great potential for displays. However, there are several significant problems. One is to make the device efficient, particularly as measured by its external power efficiency and its external quantum efficiency. Another is to optimise (e.g. to reduce) the voltage at which peak efficiency is obtained. Another is to stabilise the voltage characteristics of the device over time. Another is to increase the lifetime of the device.

To this end, numerous modifications have been made to the basic device structure described above in order to solve one or more of these problems.

One such modification is the provision of a layer of conductive polymer between the light-emissive organic layer and one of the electrodes. It has been found that the provision of such a conductive polymer layer can improve the turn-on voltage, the brightness of the device at low voltage, the efficiency, the lifetime and the stability of the device. In order to achieve these benefits these conductive polymer layers typically may have a sheet resistance less than 10⁶ Ohms/square, the conductivity being controllable by doping of the polymer layer. It may be advantageous in some device arrangements to not have too high a conductivity. For example, if a plurality of electrodes are provided in a device but only one continuous layer of conductive polymer extending over all the electrodes, then too high a conductivity can lead to lateral conduction and shorting between electrodes.

The conductive polymer layer may also be selected to have a suitable workfunction so as to aid in hole or electron injection and/or to block holes or electrons. There are thus two key electrical features: the overall conductivity of the polymer composition; and the workfunction of the polymer composition. The stability of the composition and reactivity with other components in a device will also be critical in providing an acceptable lifetime for a practical device. The processability of the composition will be critical for ease of manufacture.

One example of a suitable conductive polymer for use as a hole injection layer between the anode and the light-emissive organic layer is polystyrene sulphonic acid doped polyethylene dioxythiophene (“PEDOT-PSS”)—see EP 0,686,662. This composition provides an intermediate ionisation potential (intermediate between the ionisation potential of the anode and that of the emitter) a little above 4.8 eV, which helps the holes injected from the anode to reach the HOMO level of a material, such as an organic light emissive material or hole transporting material, in an adjacent layer of an opto-electrical device. The PEDOT-PSS may also contain epoxy-silane to produce cross-linking so as to provide a more robust layer. Typically the thickness of the PEDOT/PSS layer in a device is around 50 nm. The conductance of the layer is dependent on the thickness of the layer.

PEDOT:PSS is water soluble and therefore solution processible. The provision of PEDOT:PSS between an ITO anode and an emissive layer increases hole injection from the ITO to the emissive layer, planarises the ITO anode surface, preventing local shorting currents and effectively makes energy difference for charge injection the same across the surface of the anode.

In practice, it has been found that using an excess of PSS can improve device performance and, in particular, can increase lifetime. Furthermore, excess PSS results in the composition being easier to ink jet print. By “excess PSS” is meant more PSS than is needed to prevent the PEDOT falling out of solution. Thus, it is evident that it is advantageous to provide PSS in excess for ease of manufacture of a device and so as to produce a device with better performance and lifetime. However, there is always a desire to improve further the performance and lifetime of devices and make the manufacturing process easier and cheaper. Accordingly, alternatives to the PEDOT-PSS system having excess PSS are sought.

Without being bound by theory, one possible limitation on the lifetime of devices using the aforementioned PEDOT-PSS system is that the provision of such a large excess of PSS results in a composition which is very acidic. This may cause several problems. For example, providing a high concentration of strong acid in contact with ITO may cause etching of the ITO with the release of indium, tin and oxygen components into the PEDOT which degrades the overlying light emitting polymer. Furthermore, the acid may interact with light emitting polymers resulting in charge separation which is detrimental to device performance.

An additional problem with the PEDOT-PSS system is that it is an aqueous system. It would be advantageous if an organic solvent system could be developed such that all organic layers of a device could be deposited from organic solvents.

There are several prior art documents which disclose the possibility of co-evaporating a small molecule hole transporter with tetracyanoquinodimethane (TCNQ) or tetrafluoro-tetracyanoquinodimethane (F4TCNQ) in order to form a conductive hole transporting layer. See, for example, Appl. Phys. Lett., vol 82, no 26, p 4815; Appl. Phys. Lett., vol 79, no 24, p 4040; Appl. Phys. Lett., vol 73, no 22, p 3202; Organic Electronics, 3 (2002), p 53; Organic Electronics, 2 (2001), p 97; J. Appl. Phys., vol 94, no 1, p 359; J. Appl. Phys., vol 87, no 9, p 4340; and J. Org. Chem. 2002, 67, p 8114. However, depositing materials by evaporation is time consuming and expensive, particularly when large areas are required. Furthermore, such a technique requires further steps, such as photolithography, in order to produce a patterned layer, which adds further time and expense to a manufacturing process.

U.S. Pat. No. 6,835,803 discloses the possibility of producing a composition comprising semiconductive polymers which are derivatised with a dopant moiety

J. Appl. Phys. 97, 103705 (2005) discloses electrical doping of poly(9,9-dioctylfluorenyl-2,7-diyl) with tetrafluorotetracyanoquinodimethane by solution method.

In light of the above, there is a desire to provide an alternative to the aforementioned systems, preferably one which results in better device performance, lifetime and ease of manufacture.

It is an aim of the present invention is to solve one or more of the problems outlined above.

### SUMMARY OF INVENTION

According to a first aspect of the present invention there is provided a conductive polymer composition comprising: a polymer having a HOMO level greater than or equal to −5.7 eV and a dopant having a LUMO level less than −4.3 eV.

To avoid any misunderstanding in relation to these negative values, the range “greater than or equal to −5.7 eV” encompasses −5.6 eV and excludes −5.8 eV, and the range “less than −4.3 eV” encompasses −4.4 eV and excludes −4.2 eV.

Preferably, the polymer has a HOMO greater than or equal to −5.5 eV, −5.3 eV or −5.0 eV.

It has been found that the combination of a polymer having a HOMO level greater than or equal to −5.7 eV and a dopant having a LUMO level less than −4.3 eV results in a conductive composition which has excellent hole transport and injection properties compared with prior art compositions. While not been bound by theory, it is postulated that a polymer having a HOMO level of greater than or equal to −5.7 eV provides excellent hole transport and injection properties while the dopant must have a LUMO level less than −4.3 eV in order to readily accept electrons from such a polymer in order to create free holes in the polymer. Accordingly, it is the combination of a polymer having a HOMO level greater than or equal to −5.7 eV and a dopant having a LUMO level less than −4.3 eV that is required in order to achieve good hole transport and injection. This contrasts with, for example, the composition described in J. Appl. Phys. 97, 103705 (2005) which comprises the polymer poly(9,9-dioctylfluorenyl-2,7-diyl) which has a HOMO level of −5.8 eV. Furthermore, the aforementioned combination of features is not disclosed in U.S. Pat. No. 6,835,803.

Preferably, the HOMO of the polymer is higher (i.e. less negative) than the LUMO of the dopant. This provides better electron transfer from the HOMO of the polymer to the LUMO of the dopant. However, charge transfer is still observed if the HOMO of the polymer is only slightly lower than the LUMO of the dopant.

Preferably the polymer has a HOMO in the range 4.6-5.7 eV, more preferably 4.6-5.5 eV. This allows for good hole injection from the anode into an adjacent semi-conductive hole transporter and/or emitter.

Preferably, the dopant is a charge neutral dopant, most preferably optionally substituted tetracyanoquinodimethane (TCNQ), rather than an ionic species such as the protonic acid doping agents referred to in U.S. Pat. No. 6,835,803. As has previously been stated, providing a high concentration of acid in contact with ITO may cause etching of the ITO with the release of indium, tin and oxygen components which degrades the overlying light emitting polymer. Furthermore, the acid may interact with light emitting polymers resulting in charge separation which is detrimental to device performance. As such, a charge neutral dopant such as TCNQ is preferred.

While previously it was known that TCNQ can be co-evaporated with a small molecule hole transporter in order to form a conductive hole transporting layer, and semiconductive polymers can be formed which are derivatised with a redox group based on TCNQ, the present inventors have surprisingly found that TCNQ (or other dopants having a LUMO level less than −4.3 eV) can be used to dope polymers having a HOMO level greater than or equal to −5.7 eV in order to form conductive polymer compositions for use as improved hole injecting layers in an organic light-emissive device. The polymer is oxidized to produce a polymer radical cation which acts as a hole transporter. The TCNQ ionises to produce an anion which acts as a counter ion to stabilise the charge on the polymer. Such a polymer composition differs from the polymers disclosed in U.S. Pat. No. 6,835,803 which are doped with ionic species. Furthermore, the compositions of the present invention are advantageous over the co-evaporated small molecule layers previously known in that they are solution processable which makes them cheaper and easier to use, and allows for patterned layers to be directly written by, for example, ink jet printing.

Preferably, the optionally substituted TCNQ is a fluorinated derivative, for example, tetrafluoro-tetracyanoquinodimethane (F4TCNQ). It has been found that this derivative is particularly good at accepting electrons from a polymer in order to dope the polymer in order to make it conductive. The LUMO levels of TCNQ and F4TCNQ are −5.07 eV and −5.46 eV respectively, as measured by the method described in more detail in the examples below. On this point, the applicants note that different measurement methods may yield different LUMO levels for the dopant; to avoid any doubt, LUMO dopant levels provided herein are as obtained by the method described in the examples below,

It will be appreciated that the deeper the LUMO of the dopant, the greater the driving force for p-doping. In one preferred embodiment, the dopant has a LUMO level less than −5.0 eV, more preferably less than −5.2 eV, most preferably less than −5.3 eV.

Other suitable dopants according to the present invention include tris(4-bromophenyl)aminium hexachloroantimonate (TBAHA); transition metal chloride p-dopants such as FeCl₃ and SbCl₅; and iodine.

In one preferred embodiment, the LUMO level of the dopant is at least 0.2 eV, and preferably 0.3 eV, less than the LUMO level of TCNQ (regardless of measurement method.)

Preferably, the dopant comprises one or more solubilising substituents. This allows the dopant to be more easily solution processed with the polymer. The solubilising substituents may be groups such as C₁₋₂₀ alkyl or alkoxy which make the dopant more soluble in organic solvents.

Preferably, the polymer per se is a charge-transporting polymer, most preferably a hole-transporting polymer. On doping the polymer, the composition must be conductive. The conductivity of the composition is preferably in the range 10⁻⁸-10⁻¹ S/cm, more preferably 10⁻⁶ S/cm to 10⁻² S/cm. However, the conductivity of the compositions can be readily varied by altering the ratio of polymer to dopant, or by using a different polymer and/or dopant, according to the particular conductivity value desired for a particular use.

Preferably, the polymer is conjugated. The polymer may comprise triarylamine and/or thiophene repeat units. Polymers comprising triarylamine repeat units have been found to be good hole transporters. The polymer may be a co-polymer of, for example, triarylamine repeat units and other repeat units such as fluorene derivatives.

Excellent material properties may be achieved by fully doping triarylamine containing conjugated polymers with TCNQ. These materials are solution processable and provide excellent conduction and charge injection in a device resulting in improved device performance.

Particularly preferred triarylamine repeat units are selected from optionally substituted repeat units of formulae 1-6:

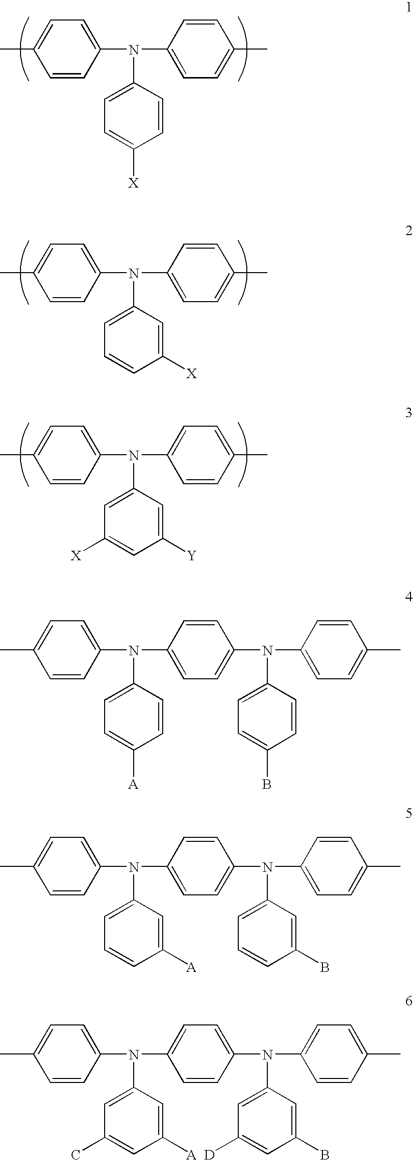

wherein X, Y, A, B, C and D are independently selected from H or a substituent group. More preferably, one or more of X, Y, A, B, C and D is independently selected from the group consisting of optionally substituted, branched or linear alkyl, aryl, perfluoroalkyl, thioalkyl, cyano, alkoxy, heteroaryl, alkylaryl and arylalkyl groups. Most preferably, X, Y, A and B are C₁₋₁₀ alkyl. The aromatic rings in the backbone of the polymer may be linked by a direct bond or a bridging atom, in particular a bridging heteroatom such as oxygen.

Also particularly preferred as a triarylamine repeat unit is an optionally substituted repeat unit of formula 6a:

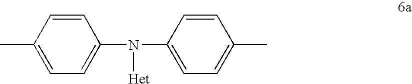

wherein Het represents a heteroaryl group.

Another preferred repeat unit has the general formula (6aa):

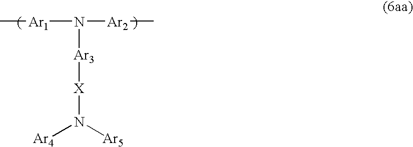

where Ar₁, Ar₂, Ar₃, Ar₄ and Ar₅ each independently represent an aryl or heteroaryl ring or a fused derivative thereof; and X represents an optional spacer group.

The polymer may also comprise thiophene units, including fused or unfused thiophene units. Thiophene units may be substituted or unsubstituted. Preferred substituents are solubilising substituents, in particular alkyl and alkoxy substituents. The thiophene units may be fused or unfused. Preferably the thiophene units are unfused. Polymers comprising thiophene units may be homopolymers such as poly(3-hexylthiophene) (P3HT), or copolymers such as poly(9,9′-dioctylfluorene-alt-bithiophene) (F8T2). Such polymers may provide a HOMO level greater than −5.0 eV.

Copolymers comprising one or more amine repeat units 1-6, 6a and 6aa preferably further comprise a first repeat unit selected from arylene repeat units, in particular: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirobifluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred copolymers comprise first repeat units of formula 6b:

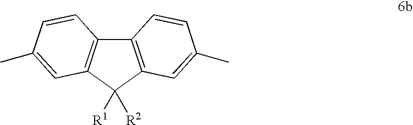

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

The optionally substituted TCNQ dopant may be blended with the polymer as a mixture. In one embodiment the dopant is mixed with monomer prior to polymerisation to form the polymer. In another embodiment, the polymer is synthesised and subsequently mixed with the dopant.

One problem with such methods is that of obtaining a good blend in which the TCNQ dopant is thoroughly dispersed through the polymer. In particular, it is difficult to find a suitable solvent for both the polymer and the optionally substituted TCNQ dopant. The inventors have found that suitable solvents include halogenated solvents, such as chlorinated benzene derivatives and chloroform; cyano derivatives; mono- or poly-alkylated benzene derivatives such as toluene and xylene; and heteroaromatic solvents such as thiophene.

As an alternative to providing a blend of the optionally substituted TCNQ dopant and the polymer, the optionally substituted TCNQ dopant may be chemically bound to the polymer. This arrangement avoids the problems of finding a suitable solvent for both components and makes the dispersion of the dopant through the polymer more controllable. This allows for easy solution processing of the composition. Furthermore, a more intimate relation between the polymer and the dopant can be achieved and this can increase charge transfer between the polymer and dopant, thus increasing conductivity. Additionally, binding the dopant to the polymer prevents the dopant from diffusing through a device in use. It is advantageous for the dopant counter ion to remain in position for stabilizing the conductive polymer ion. This aids conduction.

Preferably the dopant is provided in a pendant group rather than in the polymer backbone. Such an arrangement is advantageous as the polymer can be selected to have suitable electronic energy levels for good charge transport and hole injection. Providing the dopant in a pendant group will not unduly affect these energy levels compared with introducing the dopant into the polymer backbone which may impede charge transport and lower charge injection by unduly modifying the electronic energy levels of the polymer.

Preferably, the polymer is cross-linkable to form a matrix. A cross-linked matrix is advantageous for preventing diffusion of undesirable species in a device. Further, a cross-linked matrix is advantageous for preventing diffusion of the dopant in a blend. Cross-linking can make a layer of the material more robust and allows another layer to be deposited thereon without dissolution and mixing of the layers.

According to another aspect of the present invention there is provided an electrical device, preferably an opto-electronic device, comprising a conductive polymer composition as described herein. Preferably the electrical device comprises an anode, a cathode, and an organic semi-conductive layer between the anode and cathode. The conductive polymer composition may be provided in a layer between the anode and the organic semi-conductive layer. The organic semi-conductive layer preferably is light-emissive. The anode preferably comprises ITO.

The organic semi-conductive layer may comprise one or more of a hole transporter, an electron transporter and a light emissive material. One or more further organic semi-conductive layers may be provided between the anode and cathode. For example, it is advantageous to provide a hole-transporting layer between the conductive polymer layer and the light-emissive layer. In a particularly preferred arrangement, the hole transporting material in the light-emissive layer and/or the hole transporting layer comprises the same polymer as that used in the conductive polymer layer. This provides good electronic energy level matching for improved charge injection from the conductive layer into the semiconductive region.

A layer comprising the conductive polymer composition of the invention is preferably formed by deposition of the composition from solution, as set out above.

In the case where a device comprises multiple layers, in particular organic layers, and one or more layers are formed by solution processing, it is necessary to ensure that (a) the solvent used to form the solution processed layer does not dissolve any underlying layers, and (b) the solution processed layer is not itself dissolved during deposition of a subsequent layer.

Methods of avoiding dissolution of an underlying layer include crosslinking the underlying layer in order to render it insoluble; annealing the underlying layer, without necessarily crosslinking it, to render it less susceptible to dissolution; and selecting a solvent for a subsequent layer that does not dissolve the underlying layer.

Thus, for example, a layer comprising the conductive polymer composition of the invention may be provided with crosslinking groups that are crosslinked following deposition of a solution comprising the composition. Crosslinking groups may be blended with the composition, or they may be provided as side groups of the polymer.

Alternatively, one or more layers of a device comprising multiple layers may be formed by a non-solvent based method in order to avoid such dissolution. Examples of such methods include thermal evaporation; thermal transfer of material from a donor sheet carrying the material: and lamination. For example, in the case where the conductive polymer composition of the invention provides a hole injection layer, a subsequent hole transport layer or electroluminescent layer may formed on a substrate by spin coating hole transport material or electroluminescent material onto the substrate; evaporating the solvent from the resultant film; de-laminating the film from the substrate; and laminating the film onto the hole injection layer.

According to another aspect of the present invention there is provided an electronic device (e.g. OLED, photovoltaic (PV) device, field effect transistor (FET)) comprising a conductive layer of conjugated organic material doped with a charge-neutral dopant. Preferably, the electronic device is an OLED wherein the conductive layer is a hole transporting layer.

According to another aspect of the present invention there is provided an electrical device, preferably an opto-electronic device, comprising an anode, a cathode, and an organic semi-conductive layer comprising a polymer between the anode and the cathode, the device further comprising a layer of a conductive polymer composition comprising a polymer and a dopant, the layer of conductive polymer composition being disposed between the anode and the cathode, the polymer in the conductive polymer composition comprising a repeat unit and the polymer in the organic semi-conductive layer comprising the same repeat unit.

The layer of conductive polymer composition may comprise dopant uniformly distributed through the bulk of the composition. However, it may also be advantageous to provide a non-uniform distribution of dopant, such as a layer comprising a concentration gradient, or a high concentration of dopant at one surface and a low concentration at an opposing surface of the layer. For example, the layer may comprise dopant concentrated at the interface with the anode in order to improve hole injection from the anode. Moreover, if the concentration of dopant at the opposing surface of the layer is sufficiently low then quenching of luminescence from this side of the layer may be minimised. A single layer may thus provide both functions of effective hole injection/transport and electroluminescence.

Preferably, the polymers in the semi-conductive and conductive layers are substantially identical. Most preferably, they are charge-transporting polymers per se, such as a hole transporting polymer with the conductive polymer layer being disposed between the anode and the semi-conductive layer to provide hole injection into the semi-conductive layer. By providing the conductive and semi-conductive layers with similar polymers, good electronic energy level matching is achieved resulting in improved charge injection from the conductive layer into the semi-conductive layer. The polymer and dopant is preferably one of those described in relation to the first aspect of the invention. The dopant is preferably capable of accepting electrons such as those described in relation to the first aspect of the present invention.

According to another aspect of the present invention there is provided a method of manufacturing an electrical device as described herein, wherein the conductive polymer composition is deposited from solution, for example, by spin coating or ink jet printing. The composition may be heated after being deposited so as to cross-link the polymer. This heating step may be performed prior to deposition of an overlying layer. Preferably, when a semiconductive polymer is deposited over the conductive polymer layer, the semiconductive polymer is deposited from the same solvent as that used to deposit the conductive polymer. Using the same solvents for the different organic layers of a device simplifies the manufacturing process. A non-aqueous solvent may be used for the layers.

According to another aspect of the present invention there is provided a method of forming a film, preferably as a layer of an electronic device, comprising the step of depositing a composition as described herein from solution.

The present invention provides an alternative to the provision of excess strong acid in known conductive polymer compositions. In particular, embodiments of the present invention provide an alternative to the provision of PEDOT-PSS formulations having excess PSS known in the art.

It is envisaged that conductive polymer compositions of the present invention may be used in an electrical device, particularly an opto-electronic device, as a hole injection material or as an anode if the composition is tuned for high conductivity. A preferred opto-electronic device comprises an organic light emitting device (OLED). It is also envisaged that the conductive polymer compositions of the present invention may be used in capacitors and as anti-static coatings on lenses.

### BRIEF DESCRIPTION OF THE DRAWINGS

Embodiments of the present invention will now be described by way of example only with reference to the accompanying drawing in which:

FIG. 1 shows an organic light-emissive device according to an embodiment of the present invention.

FIG. 2 shows the absorption spectrum of F4TCNQ-doped P3HT thin films.

FIG. 3 shows the conductivity of compositions according to the inventions.

FIG. 4a shows the hole current for doped and undoped P3HT thin films in diode configuration.

FIG. 4b shows the hole current for doped and undoped PFB thin films in diode configuration.

FIG. 4c shows the hole current for doped and undoped TFB thin films in diode configuration.

FIG. 4d shows the hole current for doped and undoped F8BT thin films in diode configuration.

### DETAILED DESCRIPTION OF EMBODIMENTS OF THE INVENTION

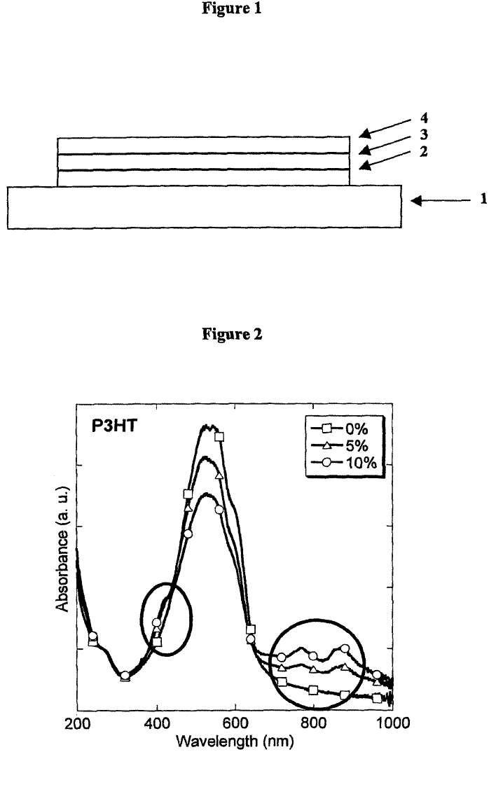

The device shown in FIG. 1 comprises a transparent glass or plastic substrate 1, an anode 2 of indium tin oxide and a cathode 4. An electroluminescent layer 3 is provided between anode 2 and cathode 4.

Further layers may be located between anode 2 and cathode 3, such as charge transporting, charge injecting or charge blocking layers.

In accordance with an embodiment of the present invention, a conductive hole injection layer formed of a conductive polymer composition is located between the anode 2 and the electroluminescent layer 3 to assist hole injection from the anode into the layer or layers of semiconducting polymer.

The hole injection layer may be made by mixing a fluorene-triaryl amine or thiophene co-polymer with F4TCNQ in a suitable solvent, such as toluene for instance. The resultant composition may be spin coated or ink jet printed to form a layer on the anode.

The hole injection layer located between anode 2 and electroluminescent layer 3 has a HOMO level of less than or equal to 5.7 eV, more preferably around 4.6-5.5 eV.

If present, an electron transporting layer located between electroluminescent layer 3 and cathode 4 preferably has a LUMO level of around 3-3.5 eV.

Electroluminescent layer 3 may consist of the electroluminescent material alone or may comprise the electroluminescent material in combination with one or more further materials. In particular, the electroluminescent material may be blended with hole and/or electron transporting materials as disclosed in, for example, WO 99/48160. Alternatively, the electroluminescent material may be covalently bound to a charge transporting material.

Cathode 4 is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of calcium and aluminium as disclosed in WO 98/10621, elemental barium disclosed in WO 98/57381, Appl. Phys. Lett. 2002, 81(4), 634 and WO 02/84759 or a thin layer of dielectric material to assist electron injection, for example lithium fluoride disclosed in WO 00/48258 or barium fluoride, disclosed in Appl. Phys. Lett. 2001, 79(5), 2001. In order to provide efficient injection of electrons into the device, the cathode preferably has a workfunction of less than 3.5 eV, more preferably less than 3.2 eV, most preferably less than 3 eV.

Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

In a practical device, at least one of the electrodes is semi-transparent in order that light may be absorbed (in the case of a photoresponsive device) or emitted (in the case of an OLED). Where the anode is transparent, it typically comprises indium tin oxide. Examples of transparent cathodes are disclosed in, for example, GB 2348316.

The embodiment of FIG. 1 illustrates a device wherein the device is formed by firstly forming an anode on a substrate followed by deposition of an electroluminescent layer and a cathode. However it will be appreciated that the device of the invention could also be formed by firstly forming a cathode on a substrate followed by deposition of an electroluminescent layer and an anode.

Various polymers are useful as emitters and/or charge transporters. Some examples of these are given below. The repeat units discussed below may be provided in a homopolymer, in a blend of polymers and/or in copolymers. It is envisaged that conductive polymer compositions according to embodiments of the present invention may be used with any such combination. In particular, conductive polymer layers of the present invention may be tuned in relation to the particular emissive and charge transport layers utilized in a device in order to obtain a desired conductivity, HOMO and LUMO.

Polymers may comprise a first repeat unit selected from arylene repeat units, in particular: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably repeat units of formula (8):

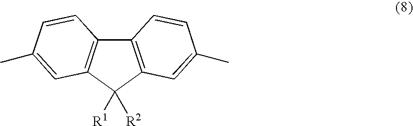

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

A polymer comprising the first repeat unit may provide one or more of the functions of hole transport, electron transport and emission depending on which layer of the device it is used in and the nature of co-repeat units.

A homopolymer of the first repeat unit, such as a homopolymer of 9,9-dialkylfluoren-2,7-diyl, may be utilised to provide electron transport.

A copolymer comprising a first repeat unit and a triarylamine repeat unit may be utilised to provide hole transport and/or emission.

Particularly preferred hole transporting polymers of this type are AB copolymers of the first repeat unit and a triarylamine repeat unit.

A copolymer comprising a first repeat unit and heteroarylene repeat unit may be utilised for charge transport or emission. Preferred heteroarylene repeat units are selected from formulae 9-23:

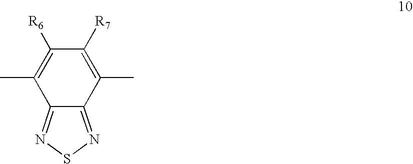

wherein R₆ and R₇ are the same or different and are each independently hydrogen or a substituent group, preferably alkyl, aryl, perfluoroalkyl, thioalkyl, cyano, alkoxy, heteroaryl, alkylaryl or arylalkyl. For ease of manufacture, R₆ and R₇ are preferably the same. More preferably, they are the same and are each a phenyl group.

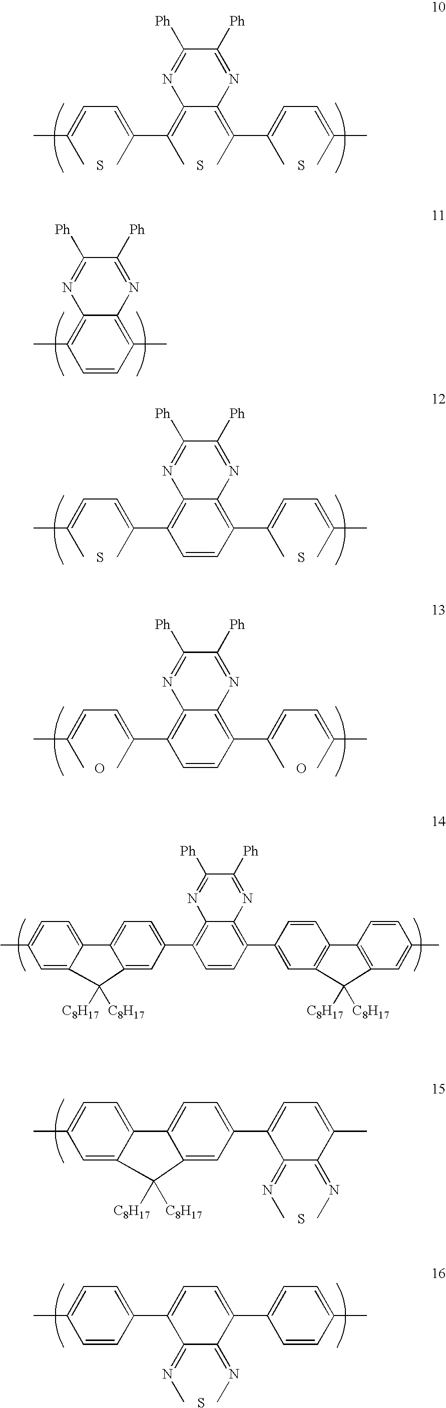

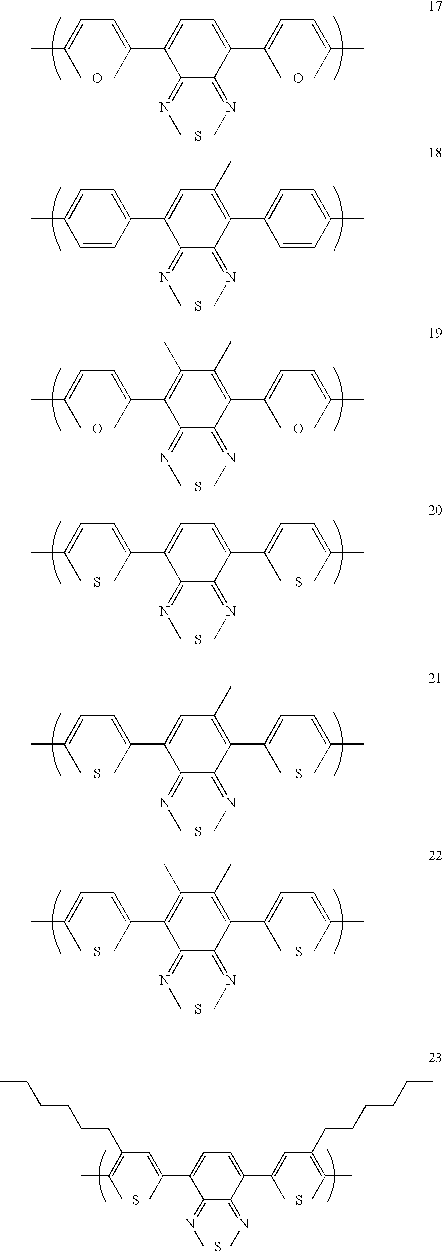

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality.

The different regions within such a polymer may be provided along the polymer backbone, as per U.S. Pat. No. 6,353,083, or as groups pendent from the polymer backbone as per WO 01/62869.

Preferred methods for preparation of these polymers are Suzuki polymerisation as described in, for example, WO 00/53656 and Yamamoto polymerisation as described in, for example, T. Yamamoto, “Electrically Conducting And Thermally Stable □-Conjugated Poly(arylene)s Prepared by Organometallic Processes”, Progress in Polymer Science 1993, 17, 1153-1205. These polymerisation techniques both operate via a “metal insertion” wherein the metal atom of a metal complex catalyst is inserted between an aryl group and a leaving group of a monomer. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units and end groups comprising aryl groups as illustrated throughout this application may be derived from a monomer carrying a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular, in particular AB, copolymers may be prepared when both reactive groups of a first monomer are boron and both reactive groups of a second monomer are halogen.

As alternatives to halides, other leaving groups capable of participating in metal insertion include tosylate, mesylate, phenyl sulfonate and triflate.

A single polymer or a plurality of polymers may be deposited from solution to form layer 5. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary for example for lighting applications or simple monochrome segmented displays.

Inkjet printing is particularly suitable for high information content displays, in particular full colour displays. Inkjet printing of OLEDs is described in, for example, EP 0880303.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

Phosphorescent materials are also useful and in some applications may be preferable to fluorescent materials. One type of phosphorescent material comprises a host and a phosphorescent emitter in the host. The emitter may be bonded to the host or provided as a separate component in a blend.

Numerous hosts for phosphorescent emitters are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in Ikai et al. (Appl. Phys. Lett., 79 no. 2, 2001, 156); and triarylamines such as tris-4-(N-3-methylphenyl-N-phenyl)phenylamine, known as MTDATA. Homopolymers are also known as hosts, in particular poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; and poly(para-phenylenes) in J. Mater. Chem. 2003, 13, 50-55.

Preferred phosphorescent metal complexes comprise optionally substituted complexes of formula (24):

ML¹_{q}L²ᵣL³ₛ (24)

wherein M is a metal; each of L¹, L² and L³ is a coordinating group; q is an integer; r and s are each independently 0 or an integer; and the sum of (a.q)+(b.r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, palladium, rhenium, osmium, iridium, platinum and gold.

Suitable coordinating groups for the f-block metals include oxygen or nitrogen donor systems such as carboxylic acids, 1,3-diketonates, hydroxy carboxylic acids,

Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals form organometallic complexes with carbon or nitrogen donors such as porphyrin or bidentate ligands of formula (25):

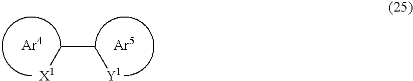

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

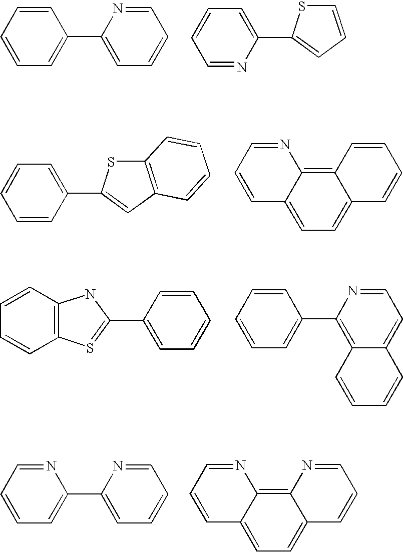

Each of Ar⁴ and Ar⁵ may carry one or more substituents. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

Such host-emitter systems are not limited to phosphorescent devices. A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014].

A wide range of fluorescent low molecular weight metal complexes may be used with the present invention. A preferred example is tris-(8-hydroxyquinoline)aluminium. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

The present invention provides conductive polymer compositions which do not degrade the above-described components of opto-electrical devices. Furthermore the conductive polymer compositions of the present invention can be tuned according to the desired properties of the composition and the resultant device. In particular, the conductive polymer compositions can be tuned according to which of the above-described components are included in the device in order to optimise performance.

While this invention has been particularly shown and described with reference to preferred embodiments thereof, it will be understood by those skilled in the art that various changes in form and details may be made therein without departing from the scope of the invention as defined by the appended claims.

### F4TCNQ Doping: Experimental Details

The conjugated polymers investigated were poly(3-hexylthiophene) (P3HT, from Sigma-Aldrich), poly(9,9-dioctylfluorene-co-bis-N,N-(4-butylphenyl)-bis-N,N-phenyl-1,4-phenylenediamine) (PFB, Mₙ=54 kg/mol), poly(9,9-di-n-octylfluorene-alt-(1,4-phenylene-((4-sec-butylphenyl)imino)-1,4-phenylene) (TFB, Mₙ=66 kg/mol) and poly(9,9-di-n-octylfluorene-alt-benzothiadiazole) (F8BT, Mᵣ=62 kg/mol). F8BT, which has a HOMO of −5.9 eV, was studied for the purpose of comparison with the compositions according to the invention. F8BT, TFB and PFB were provided by Cambridge Display Technology, Ltd.

The dopant used was tetrafluoro-tetracyano-quinodimethane (F4TCNQ, from Sigma-Aldrich, and used without any further purification). The chemical structures and electronic properties of these materials are summarised in Table 1.

The redox potentials of TCNQ and F4TCNQ materials measured by cyclic voltammetry were 0.17 V and 0.53 V, (R. C. Wheland, J. L. Gillson, J. Am. Chem. Soc. 1976, 98, 3916) respectively, vs. Saturated Calomel Electrode (SCE) in acetonitrile using tetraethylammonium perchlorate as supporting electrolyte. Assuming the LUMO level of SCE as 4.94 eV, these measurements translate into LUMO levels of 5.11 eV and 5.47 eV for TCNQ and F4TCNQ materials, respectively. Similar measurements were performed on TCNQ and F4TCNQ, showing redox potentials of 0.13 V and 0.52 V, (A. F. Garito, A. J. Heeger, Acc. Chem. Res. 1974, 7, 232) respectively, in acetonitrile vs. SCE. This implies LUMO levels of 5.07 eV and 5.46 eV, respectively.

TABLE 1

| | | Lowest | Highest |
|---|---|---|---|
| | | Unoccupied | Occupied |
| | | Molecular | Molecular |
| | | Orbital | Orbital |
| | | (LUMO) | (HOMO) |
| Materials | Chemical Structure | (eV) | (eV) |
| P3HT | 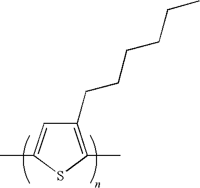 | −3.0 | −4.6 |
| PFB | 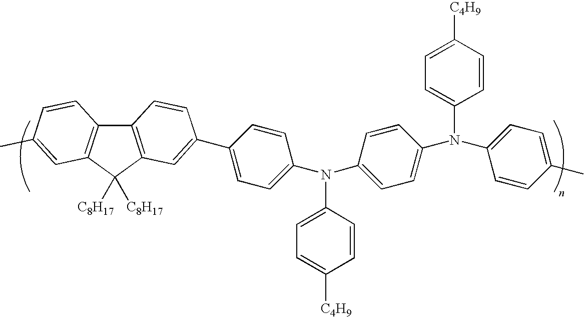 | −2.3 | −5.1 |
| TFB | 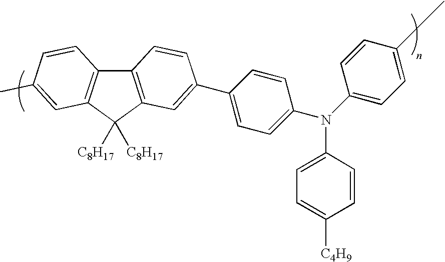 | −2.3 | −5.3 |
| F8BT | 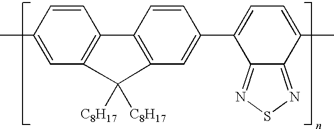 | −3.5 | −5.9 |
| F4TCNQ | 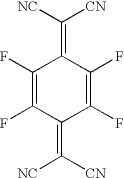 | −5.46 | −8.3 |

F4TCNQ materials were able to dissolve in range of organic solvents, including toluene, chloroform, chlorobenzene, thiophene and xylene, to produce a concentration of <0.2% w/v. Polymer solutions were prepared by dissolving each material separately to produce a concentration of 1.6% w/v for PFB, TFB and F8BT (in toluene) and 1.0% w/v for P3HT (in thiophene).

For doped solutions, appropriate quantity of F4TCNQ solutions (from common solvent) were added into the polymer solutions to achieve 5%, 10%, 15% or 20% w/w (dopant to polymer weight ratio) doping, while maintaining the same polymer concentration in the solutions (1.6° A) or 1.0% w/v) for easy film thickness control. Polymer films of ˜70-100 nm were then spin-coated from these solutions onto oxygen-plasma treated quartz substrates.

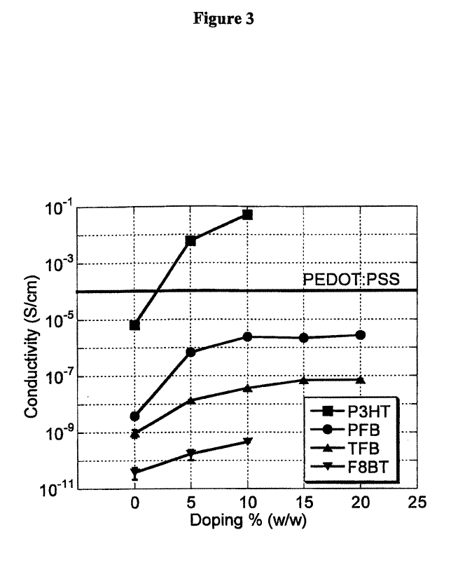

Absorption spectra for polymer thin films were acquired with a Hewlett Packard 8453 diode array spectrometer. FIG. 2 illustrates the UV-vis absorption spectra of P3HT thin films with different weight percentages of doping by F4TCNQ, normalised to the absorption shoulder of P3HT at ˜260 nm. The absorption shoulder for doped films at ˜400 nm (circled) corresponds to the main absorption peak of F4TCNQ molecules. The main absorption peak of P3HT that corresponds to π-π transition (˜530 nm) is found to decrease with increasing doping levels. Sub-gap absorption peaks at ˜750 nm and ˜875 nm observed in the doped P3HT films (not seen in both P3HT and F4TCNQ films, separately) are found to increase with doping levels. These observations indicate the presence of ground-state charge transfer from the polymer to F4TCNQ molecules.

Photoluminescence (PL) spectra and efficiencies were measured at room temperature in a nitrogen-purged integrating sphere with excitation from an argon ion laser at 355/365 nm for TFB and PFB, 457 nm for F8BT and 488 nm for P3HT. PL efficiencies were calculated as described by de Mello and co-workers (J. C. deMello, H. F. Wittmann, R. H. Friend, Adv. Mater. 9, 230 (1997)).

Table 2 shows PL efficiencies for pristine and doped films. In all cases, significant PL quenching was observed in the polymer films upon the addition of small amount of F4TCNQ dopant. This indicates efficient charge-transfer from polymers to F4TCNQ molecules, and that the F4TCNQ molecules are well-dispersed within the polymer matrix. Partial recovery of PL was observed when doped samples of PFB and TFB were annealed in N₂ environment at 200° C. for 1 hr. We attribute this to segregation of F4TCNQ molecules from the polymer matrix upon high temperature treatment.

TABLE 2

| | P3HT | PFB | TFB | F8BT |
|---|---|---|---|---|
| Pristine | 0.10 | 0.66 | 0.40 | 0.61 |
| (undoped) films | | | | |
| Doped films | 0 | 0 | 0.03 | 0.03 |
| (5% F₄TCNQ) | | | | |
| Doped films | — | 0.33 | 0.12 | — |
| (5% F₄TCNQ) | | | | |
| annealed at 200° C. | | | | |

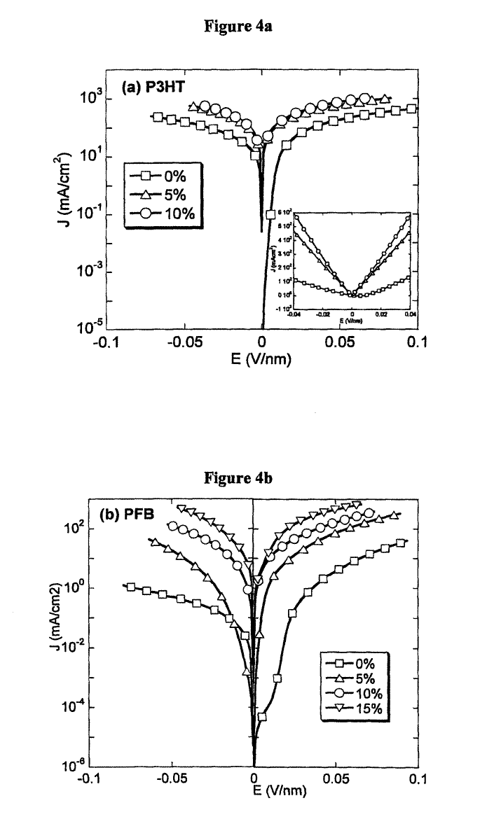

FIG. 3 shows conductivity of the conjugated polymers measured with different percentages of doping by F4TCNQ. Polymer films were deposited on substrates with inter-digitated ITO structures, where the spacing between the ITO contacts was 10 μm, 15 μm or 20 μm. The current-voltage characteristics of the films were measured in nitrogen environment, up 4 V bias in steps of 1 V. The applied electric field was ≦0.4 V/μm. The effectiveness of doping by F4TCNQ, as characterised by the rate of increase in conductivity of polymers with increasing doping concentration, is found to increase with decreasing HOMO levels (magnitude) of the polymers. The conductivity of PEDOT:PSS typically used in organic devices is included in FIG. 3 for comparison. It can be seen that doped P3HT in particular has near-metallic characteristics, whereas comparative polymer F8BT exhibits considerably lower conductivity when doped than the compositions of the invention.

Hole-only diodes were fabricated by using ITO as anode, NiCr as cathode, and (a) P3HT, (b) PFB, (c) TFB and (d) F8BT as the active layer. A 60-nm-thick hole-injecting/transporting PEDOT:PSS layer was first spin-coated onto oxygen-plasma treated ITO-coated glass substrate and then baked at 200° C. for 1 hr under N2 flow, prior to the deposition of the polymer film (ca. 70-100 nm). Finally, a ˜50 nm NiCr layer was thermally evaporated at a base pressure of ˜10⁻⁶ mbar. The current-voltage characteristics of the devices were measured under vacuum (˜10⁻¹ mbar) by a computer-controlled HP 4145 semiconductor parameter analyser. The high work function of NiCr (˜5.1 eV), along with the absence of light emission during device testing, ensures the presence (absence) of hole (electron) current during device operation.

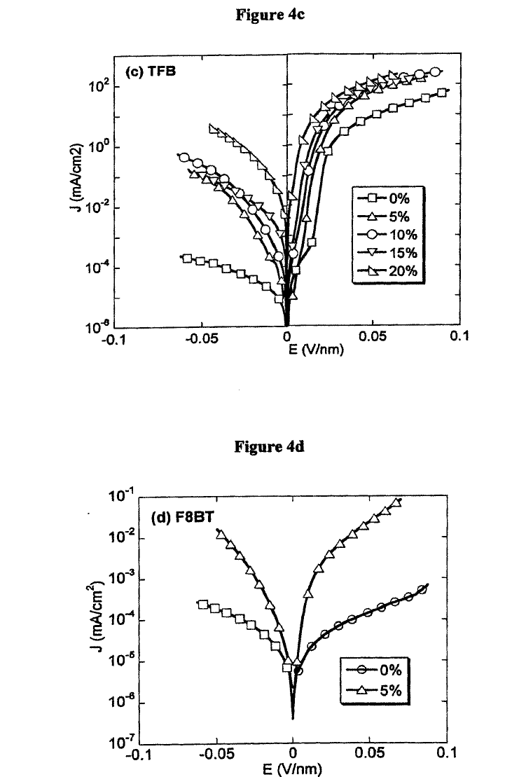

The results are shown in FIG. 4, and in all cases doping leads to significant increase in hole-current, particularly at low voltages.

Table 3 below summarises the hole-current observed at an applied field of 0.01 V/nm for devices shown in FIG. 4. P3HT (5% doped) shows ˜1 order of magnitude increase in hole-current with linear J-V characteristic, suggesting substantial increase in bulk conductivity to metallic-like conduction. PFB (5% doped) and TFB (20% doped) show ˜4 orders of magnitude increase in hole-current, indicating significant reduction in hole-injection barrier at the semiconductor interfaces. On the other hand, although F8BT (5% doped) exhibits a substantial increase in hole-current, its hole conduction is still significantly poorer than the compositions according to the invention due to its deep HOMO level (large hole-injection barrier). The effectiveness of doping decreases from P3HT to PFB to TFB to F8BT, corresponding to a gradual increase in the HOMO levels (magnitude) of these polymers (Table 1).

TABLE 3

J (mA/cm²), at 0.01 V/nm

| | P3HT | PFB | TFB | F8BT |
|---|---|---|---|---|
| Pristine | ~10¹ | ~10⁻⁴ | ~10⁻⁴ | ~10⁻⁵ |
| polymers | | | | |
| Doped | ~10² | ~10⁰ | ~10⁰ | ~10⁻⁴ |
| polymers | (5% | (5% | (20% | (5% |
| | doped) | doped) | doped) | doped) |

1. A conductive polymer composition comprising: a polymer having a highest occupied molecular orbital (HOMO) level greater than or equal to −5.7 eV and a dopant having a lowest unoccupied molecular orbital (LUMO) level less than −4.3 eV.

2. The conductive polymer composition according to claim 1, wherein the dopant is a charge neutral dopant, an optionally substituted tetracyanoquinodimethane (TCNQ), or comprises a fluorinated derivative of TCNQ.

3-5. (canceled)

6. The conductive polymer composition according to claim 1, wherein the HOMO of the polymer is higher than the LUMO of the dopant.

7. The conductive polymer composition according to claim 6, wherein the polymer has a HOMO in the range −4.6 eV to −5.5 eV.

8. (canceled)

9. The conductive polymer composition according to claim 1, wherein the polymer comprises a triarylamine repeat unit or optionally fused thiophene repeat unit.

10. The conductive polymer composition according to claim 9, wherein the triarylamine repeat unit is selected from optionally substituted repeat units of formulae 1-6: 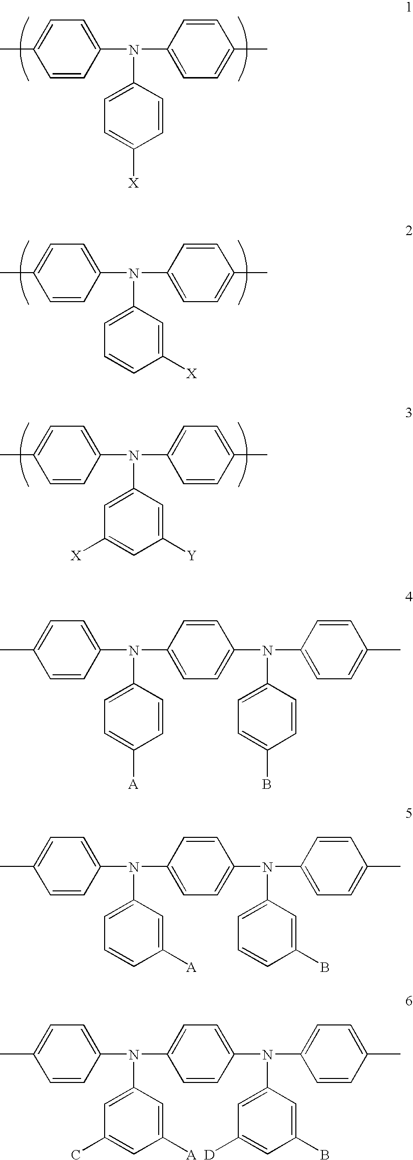
wherein X, Y, A, B, C and D are independently selected from H or a substituent group.

11. The conductive polymer composition according to claim 10, wherein one or more of X, Y, A, B, C and D is independently selected from the group consisting of optionally substituted, branched or linear alkyl, aryl, perfluoroalkyl, thioalkyl, cyano, alkoxy, heteroaryl, alkylaryl and arylalkyl groups.

12. The conductive polymer composition according to claim 11, wherein one or more of X, Y, A and B are C₁₋₁₀ alkyl.

13. (canceled)

14. The conductive polymer composition according to claim 9, wherein the triarylamine repeat unit is an optionally substituted repeat unit of formula 6a: 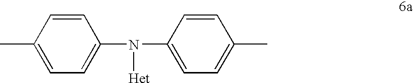
wherein Het represents a heteroaryl group.

15. The conductive polymer composition according to claim 9, wherein the triarylamine repeat unit is a repeat unit of general formula (6aa): 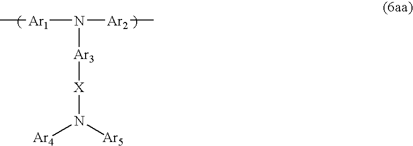
where Ar₁, Ar₂, Ar₃, Ar₄ and Ar₅ each independently represent an aryl or heteroaryl ring or a fused derivative thereof; and X represents an optional spacer group.

16. The conductive polymer composition according to claim 1, wherein the polymer is a co-polymer.

17. The conductive polymer composition according to claim 16, wherein the co-polymer comprises optionally substituted first repeat units selected from arylene repeat units, fluorene repeat units, indenofluorene repeat units, and spirobifluorene repeat units.

18. The conductive polymer composition according to claim 17, wherein the first repeat units comprise solubilising substituents.

19. The conductive polymer composition according to claim 17, wherein the first repeat units are of formula 6b: 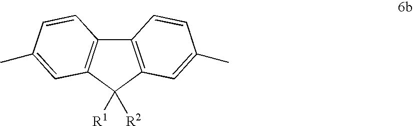
wherein R¹ and R² are independently selected from hydrogen or optionally substituted alkyl, alkoxy, aryl, arylalkyl, heteroaryl and heteroarylalkyl.

20. The conductive polymer composition according to claim 1, wherein the dopant is blended with the polymer in a mixture.

21-22. (canceled)

23. The conductive polymer composition according to claim 1, wherein the dopant is chemically bound to the polymer.

24. The conductive polymer composition according to claim 23, wherein the dopant is provided in a pendant group of the polymer.

25-26. (canceled)

27. An electrical device, comprising a conductive polymer composition as claimed in claim 1.

28. The electrical device according to claim 27, wherein the electrical device comprises an anode, a cathode, and an organic semi-conductive layer between the anode and cathode.

29-31. (canceled)

32. The electrical device according to claim 28, wherein the organic semi-conductive layer comprises one or more of a hole transporter, an electron transporter and a light emissive material.

33. (canceled)

34. The electrical device according to claim 32, wherein a hole transporting layer is provided between the conductive polymer layer and the light-emissive layer.

35. (canceled)

36. A method of manufacturing the electrical device of claim 34, wherein the conductive polymer composition is deposited from solution.

37-38. (canceled)
